(19) United States
(12) Patent Application Publication
(10) Pub. No.: US 2009/0290428 A1
(43) Pub. Date: Nov. 26, 2009

(54) READ/VERIFICATION REFERENCE VOLTAGE SUPPLY UNIT OF NONVOLATILE MEMORY DEVICE

(76) Inventor: Yu Jong NOH, Seoul (KR)

Correspondence Address: MANNAVA & KANG, P.C., 11240 WAPLES MILL ROAD, Suite 300, FAIRFAX, VA, 22030, US

(21) Appl. No.: 12/468,250

(22) Filed: May 19, 2009

(30) Foreign Application Priority Data
May 20, 2008 (KR) 10-2008-0046611

(51) Int. Cl. G11C 16/06; G11C 5/14; G11C 7/00

(52) U.S. Cl. 365/185.22; 365/226; 365/189.09; 365/211

(57) ABSTRACT

A verification reference voltage supply unit includes a reference voltage supply unit, a temperature-dependent voltage supply unit, and an amplification unit. The reference voltage supply unit is configured to supply a first reference voltage and a second reference voltage, each of which is configured to maintain a constant value irrespective of a temperature variation. The temperature-dependent voltage supply unit is configured to receive the first reference voltage and generate a temperature-dependent voltage having a voltage level that increases in proportion to a temperature increase. The amplification unit is configured to amplify the temperature-dependent voltage and the second reference voltage and generate a verification reference voltage.

### CROSS-REFERENCES TO RELATED APPLICATIONS

The present application claims priority to Korean patent application number 10-2008-0046611, filed on May 20, 2008, which is incorporated by reference in its entirety.

### BACKGROUND OF THE INVENTION

The present invention relates to a read/verification reference voltage supply unit of a nonvolatile memory device, which outputs read/verification reference voltages with different levels according to a temperature variation.

In recent years, there is an increasing demand for nonvolatile memory devices which can be electrically programmed and erased and do not need the refresh function of rewriting data at specific intervals.

The nonvolatile memory cell is an element, enabling electrical program/erase operations, and is configured to perform the program and erase operations by changing its threshold voltage as electrons are migrated by a strong electric field applied to a thin oxide layer.

The nonvolatile memory device generally includes a memory cell array in which cells for storing data are arranged in a matrix form, and a page buffer for writing memory into specific cells of the memory cell array or reading memory stored in specific cells. The page buffer includes a bit line pair connected to a specific memory cell, a register for temporarily storing data to be written into a memory cell array, or reading data of a specific cell from the memory cell array and temporarily storing the read data, a sensing node for sensing the voltage level of a specific bit line or a specific register, and a bit line select unit for controlling whether or not to connect the specific bit line to the sensing node.

A program verification operation, a read operation, etc., among between operations of this nonvolatile memory cell, are adapted to precharge a bit line to a high level and determine whether the precharged voltage level changes according to a program state of a specific memory cell. However, since voltage levels may change differently according to a temperature variation, data can be read differently from an actual state. In particular, in the state in which margin on a distribution-state basis is not sufficient as in a multi-level cell program method, each distribution may change according to a temperature variation. Accordingly, there is a need to solve this problem.

### BRIEF SUMMARY OF THE INVENTION

The present invention is directed towards a nonvolatile memory device that is able to output read/verification reference voltages with different levels according to temperature variation.

According to an aspect of the present invention, there is provided a verification reference voltage supply unit of a nonvolatile memory device flash memory device, including a reference voltage supply unit, a temperature-dependent voltage supply unit, and an amplification unit. The reference voltage supply unit is configured to supply a first reference voltage and a second reference voltage, each of which is configured to maintain a constant value irrespective of a temperature variation. The temperature-dependent voltage supply unit is configured to receive the first reference voltage and generate a temperature-dependent voltage having a voltage level that increases in proportion to a temperature increase. The amplification unit is configured to receive the temperature-dependent voltage and the second reference voltage and generate a verification reference voltage.

According to another aspect of the present invention, there is provided a verification reference voltage supply unit of a nonvolatile memory device flash memory device, including a reference voltage supply unit, a temperature-dependent voltage supply unit, a buffer unit, and an amplification unit. The reference voltage supply unit is configured to supply a first reference voltage and a second reference voltage, each of which is configured to maintain a constant value irrespective of a temperature variation. The temperature-dependent voltage supply unit is configured to receive the first reference voltage and generate a temperature-dependent voltage having a voltage level that increases in proportion to a temperature increase. The buffer unit is configured to receive the temperature-dependent voltage, translate the level of the temperature-dependent voltage, and output a translated temperature-dependent voltage. The amplification unit is configured to amplify the translated temperature-dependent voltage and the second reference voltage and generate a verification reference voltage.

### BRIEF DESCRIPTION OF THE DRAWINGS

FIG. 1 is a diagram showing variation in threshold voltage distributions according to a temperature variation at the time of a program verification operation of a typical nonvolatile memory device;

FIG. 2 is a diagram showing variation in a reference voltage according to a temperature variation in a typical nonvolatile memory device;

FIG. 3 is a diagram illustrating problems that occur when temperatures at the time of a program verification operation and a read operation differ in a typical nonvolatile memory device; and

FIG. 4 is a circuit diagram showing a verification reference voltage supply unit of a nonvolatile memory device in accordance with an embodiment of the present invention.

### DESCRIPTION OF SPECIFIC EMBODIMENT

Hereinafter, the present invention will be described in detail in connection with a specific embodiment with reference to the accompanying drawings. The present embodiment is provided to complete the disclosure of the present invention and to allow those having ordinary skill in the art to understand the scope of the present invention.

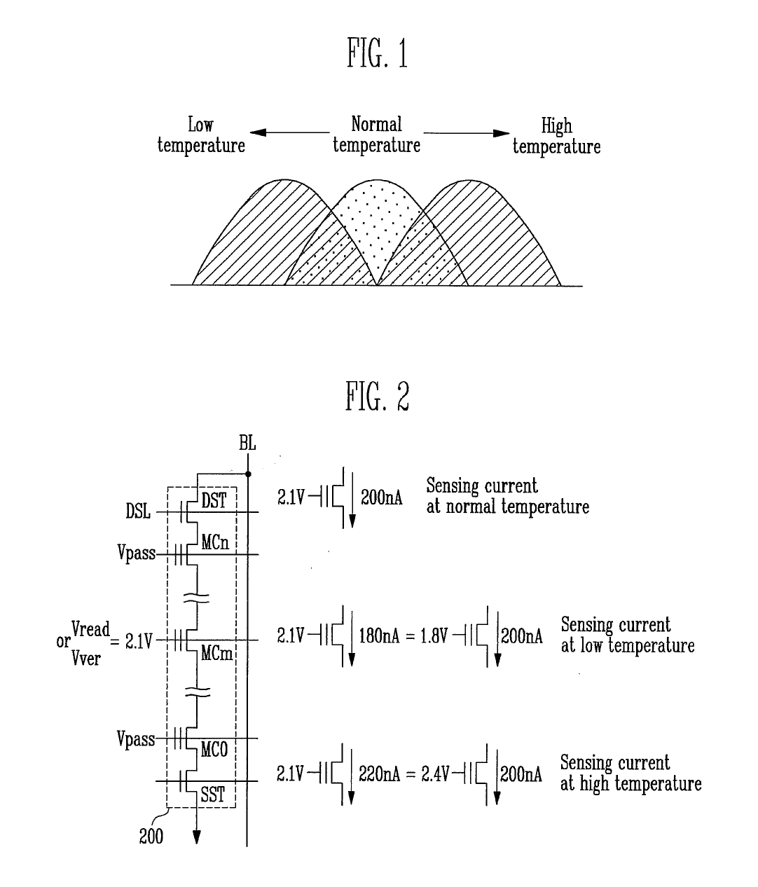

FIG. 1 is a diagram showing a variation in threshold voltage distributions according to a temperature variation at the time of a program verification operation of a typical nonvolatile memory device.

From FIG. 1, it can be seen that, assuming that the time when a program verification operation is performed at a normal temperature serves as the standard, the threshold voltage lowers when the program verification operation is performed at a low temperature, and the threshold voltage rises when the program verification operation is performed at a high temperature.

A verification operation, a read operation, etc. of a nonvolatile memory device includes precharging a bit line to a high voltage, connecting the bit line to a cell string including a memory cell to be verified and read, and then determining how the voltage level of the bit line changes through a current path formed through the cell string. At this time, the voltage level precharged to the bit line varies according to a temperature variation. Typically, a high voltage Vg is applied to a gate terminal of a NMOS transistor connected to a bit line so that a precharge voltage (Vg-Vth) is applied to a source terminal of the NMOS transistor. The threshold voltage Vth varies in inverse proportion to a temperature variation. When temperature rises, the threshold voltage falls, but when temperature falls, the threshold voltage rises. Thus, when ambient temperature rises, the precharge voltage (Vg-Vth) increases, and when ambient temperature drops, the precharge voltage (Vg-Vth) decreases. Meanwhile, sensing current flowing through a cell string changes according to a variation in a precharge voltage, and a sensing current value also changes in proportion to the amount of the precharge voltage.

The above-described features are described in more detail in connection with FIG. 1. When temperature rises, the precharge voltage increases and the sensing current also increases. Thus, there appears an effect of substantially increasing a verification reference voltage. Accordingly, a program operation is performed so that a cell is programmed at the increased verification reference voltage or higher. Consequently, there is a phenomenon in which the threshold voltage of the entire memory cells is raised.

On the other hand, when temperature drops, the precharge voltage decreases and the sensing current also decreases. Thus, there appears an effect of substantially decreasing the verification reference voltage. Accordingly, a program operation is performed so that a cell is programmed only at the decreased verification reference voltage or higher. Consequently, there is a phenomenon in which the threshold voltage of the entire memory cells is lowered.

Variation in the reference voltage according to a temperature variation is described in more detail with reference to an additional drawing.

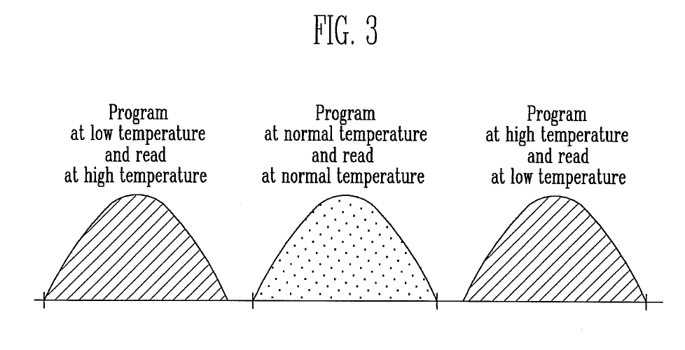

FIG. 2 is a diagram showing variation in a reference voltage according to a temperature variation in a typical nonvolatile memory device.

A plurality of memory cells MCO to MCn is connected in series to one cell string 200. The cell string 200 includes a drain select transistor DST selectively connecting the memory cell MCn and a bit line, and a source select transistor SST selectively connecting the memory cell MCO and the ground.

At the time of read/verification operations, a reference voltage Vread or Vver is applied to a word line connected to a memory cell MCm to be read, and a pass voltage Vpass of a high voltage is applied to a word line connected to the remaining memory cells. Thus, the remaining memory cells are all turned on, and it is determined whether a selected memory cell is programmed with a reference voltage or more. If the selected memory cell is programmed with the reference voltage or more, the corresponding cell is turned off, formation of a current path from a bit line to the ground is shut off, and the bit line maintains its precharged voltage level. However, if the selected memory cell is programmed with the reference voltage or less, the corresponding cell is turned on, formation of a current path from the bit line to the ground is shut off, and the bit line maintains its precharged voltage level.

As shown in the drawing, it is assumed that the reference voltage is 2.1V and a sensing current at a normal temperature is 200 nA. If a program verification operation, a read operation, etc. are performed at low temperature, the precharged voltage level is lowered and, therefore, the sensing current drops to 180 nA. Since the sensing current is lowered, even when a selected cell is programmed with the reference voltage or less, a current flow is shut off, so there is a high probability that the selected cell may be read as a programmed cell. In other words, the program verification/read operations at low temperature have an effect in which they are performed by applying a reference voltage 1.8V, which is much lower than the actual reference voltage 2.1V.

In contrast, if program verification/read operations, etc. are performed at a high temperature, the precharged voltage level is increased and therefore the sensing current rises to 220 nA. Since the sensing current is increased, even when a selected cell is programmed with the reference voltage or more, a current flow is active and thus there is a high possibility that the selected cell may be read as an unprogrammed cell. Accordingly, only when the selected cell is programmed with the reference voltage or more, the corresponding cell can be read as being turned off. In other words, the program verification/read operations at high temperature have an effect in which they are performed by applying a reference voltage 2.2V much higher than the actual reference voltage 2.1V.

Meanwhile, it will be evident to those having ordinary skill in the art that the above-mentioned numeral values are only illustrative in order to help understanding, and the scope of the present invention is not limited to the numeral values.

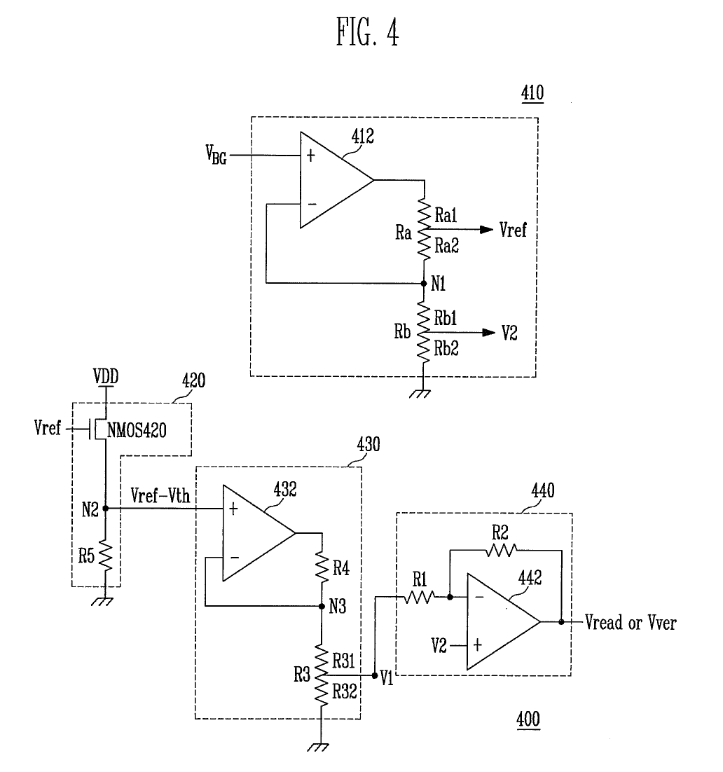

FIG. 3 is a diagram illustrating problems that occur when temperatures at the time of a program verification operation and a read operation differ in a typical nonvolatile memory device.

When temperatures at the time of a program verification operation and a read operation are the same, there is no special problem. That is, in the case in which a cell subject to a program-verification at a low temperature is read at a low temperature or in the case in which a cell subject to a program-verification at a high temperature is read at a high temperature, the threshold voltage of a programmed state can keep intact.

The problem is a case in which a cell subject to a program-verification at a low temperature is read at high temperature or a case in which a cell subject to a program-verification at a high temperature is read at a low temperature.

The former case is first described below. In the case of a cell that is subject to a program-verification at a low temperature, the cell is programmed to have a threshold voltage lower than a normal temperature, as described above. If this cell is read at a high temperature, the threshold voltage is read as being much lower than the actual threshold voltage because a reference voltage further rises when read/verification operations are performed at a high temperature as described above. In some cases, the cell may be read as being not programmed.

The latter case is described below. In the case of a cell that is subject to a program-verification at a high temperature, the cell is programmed to have a threshold voltage higher than a normal temperature, as described above. If this cell is read at a low temperature, the threshold voltage is read as being much higher than the actual threshold voltage because a reference voltage further drops when read/verification operations are performed at a low temperature as described above.

That is, when there is a difference in ambient temperature at the time of a program verification operation and ambient temperature at the time of a read operation, a cell may be read as being a different state from an actually programmed state. In particular, in the case in which a multi-level cell program is executed, there is no room in margin on a distribution basis. Accordingly, a variation in threshold voltage distributions according to a temperature variation may become more problematic.

FIG. 4 is a circuit diagram showing a verification reference voltage supply unit of a nonvolatile memory device in accordance with an embodiment of the present invention.

A verification reference voltage supply unit 400 includes a reference voltage supply unit 410, a temperature-dependent voltage supply unit 420, a buffer unit 430, and an amplification unit 440. The reference voltage supply unit 410 supplies a first reference voltage Vref and a second reference voltage V2, which maintain a constant value irrespective of a temperature variation. The temperature-dependent voltage supply unit 420 receives the first reference voltage Vref and generates a temperature-dependent voltage whose voltage level varies according to a temperature variation. The buffer unit 430 shifts the level of the temperature-dependent voltage. The amplification unit 440 amplifies the temperature-dependent voltage or the translated temperature-dependent voltage and the second reference voltage and generates a verification reference voltage Vver or a read reference voltage Vread.

The reference voltage supply unit 410 receives a band gap voltage V_{BG}, which maintains a constant value irrespective of a temperature variation and generates the first reference voltage Vref and the second reference voltage V2. To this end, the reference voltage supply unit 410 includes an OP Amp 412 having a non-inverting terminal (+) to which the band gap voltage V_{BG} is input, and a first variable resistor Ra and a second variable resistor Rb connected in series between an output terminal of the OP Amp 412 and a ground terminal. An intervening node N1 between the first variable resistor and the second variable resistor is connected to an inverting terminal (−) of the OP Amp 412.

The first reference voltage Vref is output from the first variable resistor Ra, and the second reference voltage V2 is output from the second variable resistor Rb. The band gap voltage V_{BG} is applied to the intervening node N1 according to a characteristic of an ideal OP Amp. Both the first reference voltage and the second reference voltage divide the band gap voltage.

That is, the first reference voltage Vref is decided by Equation 1.

$$Vref = ( 1 + \frac{Ra 2}{Ra} ) {V}_{BG} \qquad [ Equation 1 ]$$

The second reference voltage V2 is decided by Equation 2.

$$V 2 = \frac{Rb 2}{R b} {V}_{BG} \qquad [ Equation 2 ]$$

Meanwhile, the first reference voltage and the second reference voltage may have the same value as the band gap voltage according to a control of the variable resistors.

The temperature-dependent voltage supply unit 420 translates the first reference voltage so that the first reference voltage includes a threshold voltage component that varies according to a temperature variation. To this end, the temperature-dependent voltage supply unit 420 includes a NMOS transistor NMOS420 having a gate terminal to which the first reference voltage Vref is input and a drain terminal and a power source voltage (VDD) terminal connected to each other, and a resistor R5 connected between a source terminal of the NMOS transistor and a ground terminal. As the first reference voltage Vref is applied to the gate terminal of the NMOS transistor, a voltage (Vref-Vth) in which a threshold voltage Vth is subtracted from the reference voltage Vref is output from a intervening node N2 of the NMOS transistor and the resistor R5. As described above, the threshold voltage varies in inverse proportion to a temperature increase. The temperature-dependent voltage (Vref-Vth) output from the intervening node N2 varies in proportion to a temperature increase. That is, when temperature rises, the temperature-dependent voltage increases, and when temperature decreases, the temperature-dependent voltage decreases.

The buffer unit 430 receives the temperature-dependent voltage, translates the level of the temperature-dependent voltage, and outputs a translated temperature-dependent voltage.

The buffer unit 430 includes an OP Amp 432 having a non-inverting terminal to which the temperature-dependent voltage (Vref-Vth) is input, and a resistor R4 and a variable resistor R3 connected in series between an output terminal of the OP Amp 432 and a ground terminal. An intervening node N3 of the resistor R4 and the variable resistor R3 is connected to an inverting terminal (−) of the OP Amp 432. The buffer unit 432 has almost the same configuration as that of the reference voltage supply unit 412, and detailed description thereof is omitted for simplicity.

A translated temperature-dependent voltage V1 output from the buffer unit 430 is decided by Equation 3.

$$V 1 = \frac{R 32}{R 3} ( Vref - Vth ) \qquad [ Equation 3 ]$$

Meanwhile, the buffer unit 430 may be omitted according to the intention of a designer. If the buffer unit 430 is omitted, the temperature-dependent voltage is input to an inverting terminal (−) of the amplification unit 440.

The amplification unit 440 combines the translated temperature-dependent voltage V1 or the temperature-dependent voltage (Vref-Vth) and the second reference voltage V2 and outputs the verification reference voltage Vver or the read reference voltage Vread. In a nonvolatile memory device, a verification operation and a read operation are performed according to a substantially same principle. The verification reference voltage has its level partially translated or keeps intact and can be thus used as a read reference voltage.

To this end, the amplification unit 440 includes an OP Amp 442 having a non-inverting terminal (+) to which the second reference voltage V2 is input and an inverting terminal (−) to which the translated temperature-dependent voltage V1 or the temperature-dependent voltage (Vref-Vth) is input through a first resistor R1, and a feedback resistor R2 connecting an output terminal and the inverting terminal of the OP Amp 442. The verification reference voltage Vver or the read reference voltage Vread is decided by Equation 4 according to a configuration of the amplification unit 440.

$$\begin{matrix}Vread = V 2 + \frac{R 2}{R 1} ( V 2 - V 1 ) \\ = ( 1 + \frac{R 2}{R 1} ) V 2 - \frac{R 2 R 32}{R 1 R 3} Vref + \frac{R 2 R 32}{R 1 R 3} Vth\end{matrix} \qquad [ Equation 4 ]$$

Meanwhile, the level of an output voltage of the amplification unit 440 can be translated by controlling the resistors R1, R2, and it can be used not only as a verification reference voltage, but as a read reference voltage.

The components of the first reference voltage Vref and the second reference voltage V2 maintain a constant value irrespective of a temperature variation, but the component of the threshold voltage Vth increases in inverse proportion to a temperature increase. The verification/read voltages decrease when temperature increases, but increases when temperature decreases.

An operation of the present invention is described below with reference back to FIG. 2.

As shown in FIG. 2, there appears a phenomenon that at a low temperature, a reference voltage lower than a verification reference voltage that is actually applied seems to be applied. However, in the present invention, a verification reference voltage varying in inverse proportion to a temperature increase is applied. A verification reference voltage higher than a verification reference voltage that is applied at a normal temperature is applied. Accordingly, a problem that a threshold voltage is lowered as described above in connection with FIG. 1 can be solved.

Meanwhile, there appears a phenomenon that at a normal temperature, a reference voltage higher than a verification reference voltage that is actually applied seems to be applied. However, in the present invention, a verification reference voltage varying in inverse proportion to a temperature increase is applied. A verification reference voltage lower than a verification reference voltage that is applied at a normal temperature is applied. Accordingly, a problem that a threshold voltage is increased as discussed in connection with FIG. 1 can be solved.

Meanwhile, a state change according to a variation in an ambient temperature even when a read operation is performed can be minimized.

That is, a phenomenon that a read reference voltage lower than a read reference voltage at a normal temperature as described in connection with FIG. 2 seems to be applied can be prevented by applying a read reference voltage higher than a read reference voltage that is actually applied at a low temperature. Further, a phenomenon that a read reference voltage higher than a read reference voltage at a normal temperature as described in connection with FIG. 2 appears to be applied can be prevented by applying a read reference voltage lower than a read reference voltage that is actually applied at a high temperature.

As described above, the present invention can offer a nonvolatile memory device which can output a verification reference voltage or a read reference voltage that varies according to a temperature variation. In other words, a phenomenon that a read reference voltage lower than a read reference voltage at a normal temperature seems to be applied can be prevented by applying a read reference voltage higher than a read reference voltage that is actually applied at a low temperature. Further, a phenomenon that a read reference voltage higher than a read reference voltage at a normal temperature seems to be applied can be prevented by applying a read reference voltage lower than a read reference voltage that is actually applied at a high temperature.

The embodiment disclosed herein has been proposed to allow a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

What is claimed is:

1. A verification reference voltage supply unit of a nonvolatile memory device, comprising:
a reference voltage supply unit configured to supply a first reference voltage and a second reference voltage, each of which is configured to maintain a constant value irrespective of a temperature variation;
a temperature-dependent voltage supply unit configured to receive the first reference voltage and generate a temperature-dependent voltage having a voltage level that increases in proportion to a temperature increase; and
an amplification unit configured to receive the temperature-dependent voltage and the second reference voltage and generate a verification reference voltage.

2. The verification reference voltage supply unit of claim 1, wherein the reference voltage supply unit is configured to divide a band gap voltage having a constant value irrespective of a temperature variation and generate the first reference voltage and the second reference voltage.

3. The verification reference voltage supply unit of claim 1, wherein the reference voltage supply unit comprises:
a first OP Amp having a non-inverting terminal to receive a band gap voltage, and
a first variable resistor and a second variable resistor connected in series between an output terminal of the first OP Amp and a ground terminal,
wherein an intervening node between the first variable resistor and the second variable resistor is connected to an inverting terminal of the first OP Amp.

4. The verification reference voltage supply unit of claim 3, wherein the first reference voltage is configured to be obtained by dividing an output voltage of the output terminal of the first OP Amp according to the first variable resistor and the second variable resistor.

5. The verification reference voltage supply unit of claim 3, wherein the second reference voltage is configured to be obtained by dividing a voltage applied to the intervening node according to the second variable resistor.

6. The verification reference voltage supply unit of claim 1, wherein the temperature-dependent voltage supply unit is configured to output the temperature-dependent voltage obtained by subtracting a threshold voltage of a NMOS transistor, which varies in inverse proportion to a temperature increase, from the first reference voltage.

7. The verification reference voltage supply unit of claim 1, wherein the temperature-dependent voltage supply unit comprises:
a NMOS transistor having a gate terminal to receive the first reference voltage and having a drain terminal connected to a power source voltage terminal, and
a resistor connected between a source terminal of the NMOS transistor and a ground terminal.

8. The verification reference voltage supply unit of claim 1, wherein the amplification unit is configured to output the verification reference voltage, including a first reference voltage component, a second reference voltage component, and a threshold voltage component of an NMOS transistor, which varies in inverse proportion to a temperature increase.

9. The verification reference voltage supply unit of claim 1, wherein the amplification unit is configured to output the verification reference voltage varying in inverse proportion to a temperature increase.

10. The verification reference voltage supply unit of claim 1, wherein the amplification unit is configured to output a read reference voltage varying in inverse proportion to a temperature increase.

11. The verification reference voltage supply unit of claim 1, wherein the amplification unit comprises:
a second OP Amp having a non-inverting terminal to receive the second reference voltage;
a first resistor connected between the temperature-dependent voltage and an inverting terminal of the second OP Amp, and
a second resistor connecting an output terminal and the inverting terminal of the second OP Amp.

12. A verification reference voltage supply unit of a nonvolatile memory device, comprising:
a reference voltage supply unit configured to supply a first reference voltage and a second reference voltage, each of which is configured to maintain a constant value irrespective of a temperature variation;
a temperature-dependent voltage supply unit configured to receive the first reference voltage and generate a temperature-dependent voltage having a voltage level that increases in proportion to a temperature increase;
a buffer unit configured to receive the temperature-dependent voltage, translate a level of the temperature-dependent voltage, and output a translated temperature-dependent voltage; and
an amplification unit configured to receive the translated temperature-dependent voltage and the second reference voltage and generate a verification reference voltage.

13. The verification reference voltage supply unit of claim 12, wherein the reference voltage supply unit is configured to voltage-divide a band gap voltage having a constant value irrespective of temperature variation and generate the first reference voltage and the second reference voltage.

14. The verification reference voltage supply unit of claim 12, wherein the reference voltage supply unit comprises:
a first OP Amp having a non-inverting terminal to receive a band gap voltage, and
a first variable resistor and a second variable resistor connected in series between an output terminal of the first OP Amp and a ground terminal,
wherein an intervening node between the first variable resistor and the second variable resistor is connected to an inverting terminal of the first OP Amp.

15. The verification reference voltage supply unit of claim 14, wherein the first reference voltage is configured to be obtained by dividing an output voltage of the output terminal of the first OP Amp according to the first variable resistor and the second variable resistor.

16. The verification reference voltage supply unit of claim 14, wherein the second reference voltage is configured to be obtained by dividing a voltage applied to the intervening node according to the second variable resistor.

17. The verification reference voltage supply unit of claim 12, wherein the temperature-dependent voltage supply unit is configured to output the temperature-dependent voltage obtained by subtracting a threshold voltage of a NMOS transistor, which varies in inverse proportion to a temperature increase, from the first reference voltage.

18. The verification reference voltage supply unit of claim 12, wherein the temperature-dependent voltage supply unit comprises:
a NMOS transistor having a gate terminal to receive the first reference voltage and having a drain terminal connected to a power source voltage terminal, and
a resistor connected between a source terminal of the NMOS transistor and a ground terminal.

19. The verification reference voltage supply unit of claim 12, wherein the amplification unit is configured to output the verification reference voltage, including a first reference voltage component, a second reference voltage component, and a threshold voltage component of a NMOS transistor, which varies in inverse proportion to a temperature increase.

20. The verification reference voltage supply unit of claim 12, wherein the amplification unit is configured to output the verification reference voltage varying in inverse proportion to a temperature increase.

21. The verification reference voltage supply unit of claim 12, wherein the amplification unit is configured to output a read reference voltage varying in inverse proportion to a temperature increase.

22. The verification reference voltage supply unit of claim 12, wherein the amplification unit comprises:
a second OP Amp having a non-inverting terminal to receive the second reference voltage;
a first resistor connected between the temperature-dependent voltage and an inverting terminal of the second OP Amp, and
a second resistor connecting an output terminal and the inverting terminal of the second OP Amp.

23. The verification reference voltage supply unit of claim 12, wherein the buffer unit comprises:
a third OP Amp having a non-inverting terminal to receive the temperature-dependent voltage; and
a resistor and a variable resistor connected in series between an output terminal of the third OP Amp and a ground terminal,
wherein an intervening node between the resistor and the variable resistor is connected to an inverting terminal of the third OP Amp.
